(19) United States
(12) Patent Application Publication
(10) Pub. No.: US 2018/0049324 A1
(43) Pub. Date: Feb. 15, 2018

(54) SEMICONDUCTOR PACKAGES AND DISPLAY DEVICES INCLUDING THE SAME

(71) Applicant: Samsung Electronics Co., Ltd., Suwon-si (KR)

(72) Inventors: Jung-eun Koo, Hwaseong-si (KR); Ye-chung Chung, Hwaseong-si (KR); Yong-hoon Kim, Suwon-si (KR)

(21) Appl. No.: 15/446,255

(22) Filed: Mar. 1, 2017

(30) Foreign Application Priority Data
Aug. 12, 2016 (KR) 10-2016-0103203

(51) Int. Cl. H05K 1/18; H01L 23/00; G09G 5/18; H01L 25/065; H01L 21/48; H01L 23/538; H01L 25/18

(52) U.S. Cl. CPC H05K 1/185; H01L 23/5386; H01L 24/17; H01L 25/18; H01L 25/0655; H05K 1/181; H01L 23/5384; H01L 21/486; G09G 5/18; H01L 2924/15153; H01L 2924/19102; H01L 2924/1426; H01L 2924/141; H05K 2201/10128; H05K 2201/10515; H01L 2224/16227; H01L 2924/15724; H01L 2924/15747; H01L 2924/19041; H01L 2924/19043; G09G 2310/08

(57) ABSTRACT

Provided are a semiconductor package and a display device including the same. In some aspects, the semiconductor package may include a film substrate including a base film including cavities and a wiring layer on the base film, a semiconductor chip connected to the wiring layer and mounted on a surface of the base film, and passive devices accommodated in the cavities of the base film and electrically connected to the semiconductor chip through the wiring layer. According to other aspects a base film having at least one recess may be provided. A wiring layer may be on the base film, and a semiconductor chip may be connected to the wiring layer and mounted on a surface of the base film. At least one passive device may be in the at least one recess of the base film and electrically connected to the semiconductor chip via the wiring layer.

### CROSS-REFERENCE TO RELATED APPLICATION

This application claims the benefit of Korean Patent Application No. 10-2016-0103203, filed on Aug. 12, 2016, in the Korean Intellectual Property Office, the disclosure of which is incorporated herein in its entirety by reference.

### BACKGROUND

### 1. Technical Field

The present disclosure relates to semiconductor packages and display devices including the same, and more particularly, to semiconductor packages of a chip on film (COF) structure and display devices including the same.

### 2. Description of Related Art

As electronic products have become lighter, thinner, and smaller, a COF package technique, in which semiconductor chips are mounted on a flexible film substrate by using a flip-chip method, has been proposed as a mounting technique of high-density semiconductor chips. A COF semiconductor package may be used for panels of portable terminals such as cellular phones and personal digital assistants (PDAs), laptop computers, and display devices.

### SUMMARY

Aspects of the present disclosure may provide semiconductor packages having improved power integrity characteristics and signal integrity characteristics and display devices including the same.

According to an aspect of the present disclosure, a semiconductor package may be provided. The semiconductor package may include a film substrate, which may include a base film including cavities and a wiring layer on the base film. A first semiconductor chip may be connected to the wiring layer and may be mounted on a first surface of the base film, and first passive devices may be accommodated in the cavities of the base film and may be electrically connected to the first semiconductor chip through the wiring layer.

According to another aspect of the present disclosure, a display device may be provided. The display device may include: a source printed circuit board (PCB), a display panel spaced apart from the source PCB and capable of displaying an image, and a first semiconductor package between the source PCB and the display panel. The first semiconductor package may connect the source PCB with the display panel. The first semiconductor package may include a film substrate, which may include a base film and a wiring layer on the base film. The semiconductor package may include a timing controller on the wiring layer, a display driving chip arranged on the wiring layer, and a plurality of passive devices electrically connected to the timing controller. At least one of the passive devices may be buried in the film substrate and contact the wiring layer.

According to another aspect of the present disclosure, a semiconductor package may be provided. The semiconductor package may include a base film having at least one recess. A wiring layer may be on the base film, and a first semiconductor chip may be connected to the wiring layer and mounted on a first surface of the base film. At least one first passive device may be in the at least one recess of the base film and may be electrically connected to the first semiconductor chip via the wiring layer.

### BRIEF DESCRIPTION OF THE DRAWINGS

Aspects of the present disclosure will be more clearly understood from the following detailed description taken in conjunction with the accompanying drawings in which:

FIG. 1 is a schematic plan view of a semiconductor package according to aspects of the present disclosure;

FIG. 2 is a schematic cross-sectional view illustrating the semiconductor package taken along a line A-A′ of FIG. 1;

FIG. 3 is a schematic cross-sectional view of a semiconductor package according to aspects of the present disclosure;

FIG. 4 is a schematic cross-sectional view of a semiconductor package according to aspects of the present disclosure;

FIG. 5 is a schematic plan view of a semiconductor package according to aspects of the present disclosure

FIG. 6 is a schematic cross-sectional view illustrating the semiconductor package taken along a line B-B′ of FIG. 5;

FIG. 7 is a schematic plan view of a semiconductor package according to aspects of the present disclosure;

FIG. 8 is a schematic perspective view of a part of a display device according to aspects of the present disclosure; and

FIG. 9 is a schematic plan view of a part of a display device according to aspects of the present disclosure.

### DETAILED DESCRIPTION

Hereinafter, aspects of the present disclosure will be described in detail with reference to the accompanying drawings.

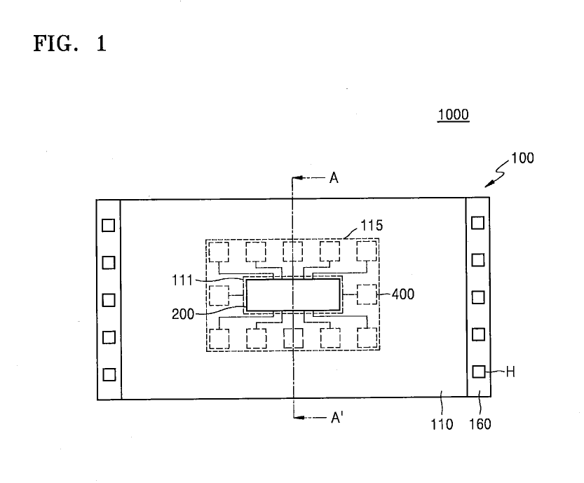

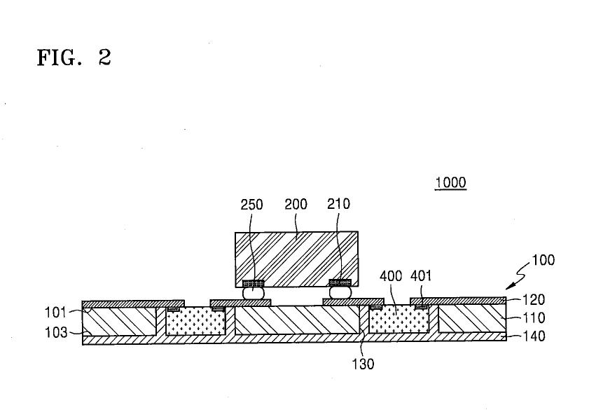

FIG. 1 is a schematic plan view of a semiconductor package 1000 according to aspects of the present disclosure. FIG. 2 is a schematic cross-sectional view illustrating the semiconductor package 1000 taken along a line A-A′ of FIG. 1.

Referring to FIGS. 1 and 2, the semiconductor package 1000 may include a film substrate 100, a first semiconductor chip 200 provided on the film substrate 100, and first passive devices 400 provided in the film substrate 100. The semiconductor package 1000 may be a chip on film (COF) semiconductor package, in which the first semiconductor chip 200 may be mounted on the film substrate 100.

The film substrate 100 may include an insulating base film 110, a wiring layer 120, and an insulating layer 140 that are conductive and formed on respective surfaces of the base film 110.

The base film 110 may be a flexible film including polyimide having a superior coefficient of thermal expansion (CTE) and durability. However, the material of the base film 110 is not limited to the polyimide. For example, the base film 110 may be made of synthetic resin such as epoxy-based resin, acrylic resin, polyether nitrile, polyether sulfone, polyethylene terephthalate, or polyethylene naphthalate.

The base film 110 may include a first mounting area 111, a passive device arranging area 115, and perforation (PF) portion 160. The first mounting area 111 may be an area on which the first semiconductor chip 200 may be mounted, and the passive device arranging area 115 may be an area in which the first passive devices 400 may be arranged. The passive device arranging area 115 may include a predetermined area on a surface of the base film 110 and a predetermined area in the base film 110. The PF portion 160 may be respectively arranged in both sides of the base film 110 and may include a plurality of PF holes H. Through the PF holes H, reeling of the base film 110 around a winding reel (not shown) or releasing of the base film 110 from the winding reel (not shown) may be controlled.

In general, since a pitch of the PF holes H may be generally constant, a length of the film substrate 100 may be determined by the number of the PF holes H. For example, the film substrate 100 illustrated herein may be a 5 PF product having five PF holes H. Meanwhile, a width and the length of the film substrate 100 may be determined by the number and sizes of semiconductor chips that are mounted on the film substrate 100, the number and sizes of passive devices in the film substrate 100, and a structure of the wiring layer 120.

The base film 110 may have cavities 130, which may penetrate through at least a part of the base film 110 to accommodate the first passive devices 400. The number of the cavities 130 may correspond to the first passive devices 400. The cavities 130 may be formed by being drilled by laser or by chemical etching. In some embodiments, the cavities 130 may vertically penetrate through the base film 110.

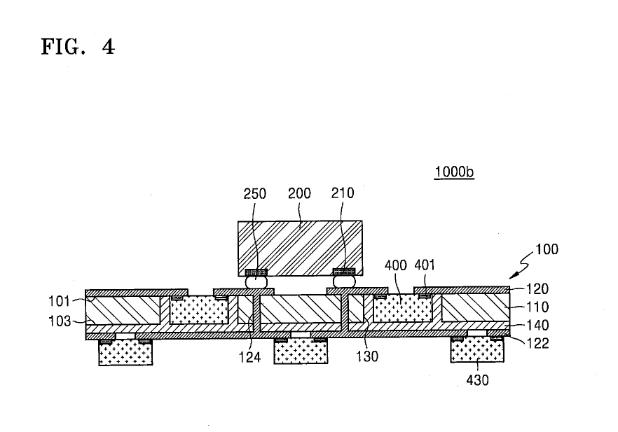

The wiring layer 120 may include an aluminum foil or a copper foil. In some embodiments, the wiring layer 120 may be formed by patterning a metal layer formed on the base film 110 by using, as examples, a casting method, a laminating method, or an electroplating method. The wiring layer 120 may be formed on only a first surface 101 of the base film 110 as illustrated in FIG. 1 and may be referred to as an upper wiring layer. However, the wiring layer 120 may be formed on both surfaces of the film substrate 100 as illustrated in FIG. 4. When the wiring layer 120 is formed on each of the both surfaces of the film substrate 100, a conductive via penetrating through the film substrate 100 may be formed.

Though not shown in FIG. 2, a protective layer to protect the film substrate 100 from external physical and/or chemical damage may be formed on the first surface 101 and a second surface 103 of the base film 110. The protective layer may cover the wiring layer 120 while exposing a predetermined part of the wiring layer 120 formed on the first surface 101 of the base film 110. The protective layer may include, for example, a solder resist or a dry film resist. Furthermore, the protective layer may include a general insulating film such as an oxide film or a nitride film.

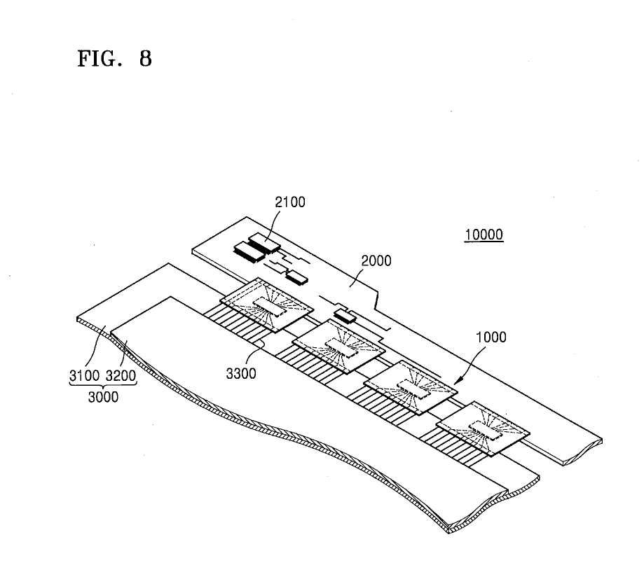

FIG. 1 schematically shows the semiconductor package 1000, and thus, a panel adhesive part and a printed circuit board (PCB) adhesive part on the base film 110 are omitted. However, the base film 110 may include the panel adhesive part adhering a display panel 3000 (of FIG. 8) to the semiconductor package 1000 with a lower side of the base film 110, and the PCB adhesive part adhering a source PCB 2000 (of FIG. 8) to the semiconductor package 1000 with an upper side of the base film 110.

In some embodiments, the first semiconductor chip 200 may be a timing controller. The timing controller may receive an image signal, may process the image signal, and may transmit various signals suitable for driving a display panel to a display driving chip (display driver IC). In more detail, the timing controller may receive a signal voltage from the source PCB, may apply the data signal to the source driver IC, and may apply the scan signal to a gate driver IC.

Furthermore, in some aspects, the first semiconductor chip 200 may be a display driving chip for driving a display. For example, the first semiconductor chip 200 may be a source driver IC, which may generate an image signal by using a data signal received from a timing controller and may output the image signal to the display panel 3000. Furthermore, the first semiconductor chip 200 may be a gate driver IC, which may output a scan signal including on/off signals of a transistor to the display panel 3000. The display driving chip may be a single chip realized by the source driver IC, the gate driver IC, and various memory devices. However, the first semiconductor chip 200 is not limited to the source drive IC or the gate driver IC. For example, when the semiconductor package 1000 illustrated in FIGS. 1 and 2 is coupled with an electronic device but not a display device, the first semiconductor chip 200 may be an integrated circuit (IC) for driving a corresponding electronic device.

The first semiconductor chip 200 may be arranged in the first mounting area 111 of the base film 110, and may be mounted on the film substrate 100 by using a flip-chip bonding method. In other words, connecting terminals 250 such as bumps or solder balls may be arranged on chip pads 210 exposed on an active surface of the first semiconductor chip 200, and the first semiconductor chip 200 may be mounted on the film substrate 100 by physically and electrically coupling the connecting terminals 250 with the wiring layer 120. Some of the chip pads 210 of the first semiconductor chip 200 may function as input terminals, and the others may function as output terminals. Though not shown in FIG. 2, the first semiconductor chip 200 may be sealed by a sealing member such as an epoxy resin to prevent physical chemical damage from the outside. Furthermore, an underfill material may be filled between the first semiconductor chip 200 and the film substrate 100.

The first passive devices 400 may be arranged in the passive device arranging area 115 in a matrix form. For example, the first passive devices 400 may include a resistor or a capacitor electrically connected to the first semiconductor chip 200, which may provide one or more electrical functions, such as to transmit power smoothly.

Although FIG. 2 illustrates that a level of a bottom surface of the first passive devices 400 is the same as that of a bottom surface of the base film 110, this is merely an example. The bottom surface of the first passive devices 400 may be higher than the bottom surface of the base film 110, or may project beyond the second surface 103 of the base film 110 as the bottom surface of the first passive devices 400 may be lower than the bottom surface of the base film 110.

The first passive devices 400 may be fixed to the film substrate 100 by the insulating layer 140 described later below. Alternatively, the first passive devices 400 may be fixed to the film substrate 100 by being inserted in the flexible base film 110.

In some embodiments, the first passive devices 400 may be arranged in the cavities 130 in a manner where the electrodes 401 provided in a side of the first passive devices 400 contact the wiring layer 120 on the first surface 101 of the base film 110. Here, the electrodes 401 of the first passive devices 400 may be electrically connected to the wiring layer 120 by a medium such as solder.

The first passive devices 400 may be arranged in an area adjacent to the first semiconductor chip 200 to reduce a length of routing paths between the first passive devices 400 and the first semiconductor chip 200. For example, the passive device arranging area 115, in which the first passive devices 400 are arranged, may overlap the first mounting area 111 on which the first semiconductor chip 200 is mounted. Furthermore, in some embodiments, the passive device arranging area 115 may surround the first mounting area 111.

The insulating layer 140 filling the cavities 130 formed in the base film 110 may be formed while covering at least some of the first passive devices 400. In more detail, the insulating layer 140 may fill a space between an inner wall of the base film 110 provided by the cavities 130 and a side surface of the first passive devices 400.

For example, the insulating layer 140 may be formed by spreading an insulating material of a liquid type in the cavities 130 of the base film 110 and curing the insulating material, or by pressing and heating the insulating material after mounting the insulating material on the second surface 103 of the base film 110. However, a method of forming the insulating layer 140 is not limited thereto. Furthermore, for example, the insulating layer 140 may include an epoxy resin, but a material of the insulating layer 140 is not limited thereto.

In some embodiments, the insulating layer 140 may cover one surface of the first passive devices 400 exposed on the second surface 103 of the base film 110. Therefore, the first passive devices 400 may be buried in the film substrate 100. However, the insulating layer 140 may cover only a side surface of the first passive devices 400 facing the inner wall of the base film 110 provided by the cavities 130.

According to aspects of the present disclosure, the length of routing paths between the first semiconductor chip 200 and the first passive devices 400 may be reduced as the first passive devices 400 are arranged in an area adjacent to the first semiconductor chip 200. Therefore, power integrity characteristics of the semiconductor package 1000 and an electronic device including the same may be improved.

Furthermore, as a plurality of first passive devices 400 are arranged in the cavities 130 of the base film 110, the first passive devices 400 may prevent an increase in a length of the film substrate 100 required for manufacturing the semiconductor package 1000 compared to when the first passive devices 400 are mounted on the first surface 101 of the base film 110. Therefore, a manufacturing cost of the semiconductor package 1000 may be reduced.

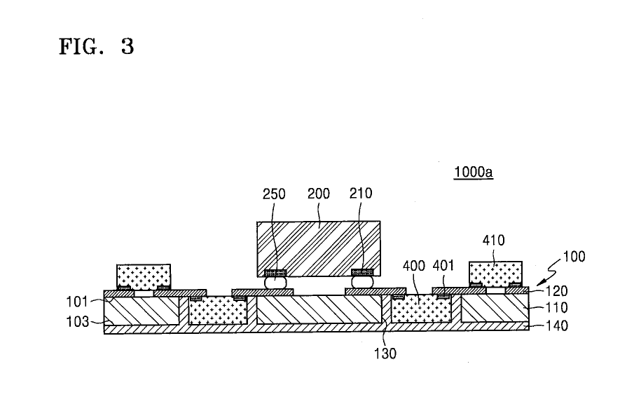

FIG. 3 is a schematic cross-sectional view of a semiconductor package 1000a according to aspects of the present disclosure.

The semiconductor package 1000a of FIG. 3 is similar to the semiconductor package 1000 of FIGS. 1 and 2 except that it further includes second passive devices 410. In FIG. 3, like reference numerals also appearing in FIGS. 1 and 2 denote like elements as those discussed with reference to FIGS. 1 and 2, and therefore, detailed descriptions thereof will not be repeated below.

Referring to FIG. 3, the semiconductor package 1000a may include the film substrate 100, the first semiconductor chip 200 on the film substrate 100, the first passive devices 400 arranged in the cavities 130 of the base film 110, and the second passive devices 410 arranged on the first surface 101 of the base film 110.

The second passive devices 410 may be arranged in the passive device arranging area 115 (of FIG. 1), and may be electrically connected to the first semiconductor chip 200. The second passive devices 410 may be mounted on the first surface 101 of the base film 110, and may be connected to the wiring layer 120 on the first surface 101 of the base film 110. In more detail, electrodes of the second passive devices 410 may be electrically connected to the wiring layer 120 by a medium such as solder.

The second passive devices 410 may be arranged in a matrix form. For example, the second passive devices 410 may be arranged in a side direction of the first semiconductor chip 200 to surround the first semiconductor chip 200.

A predetermined number of passive devices may be arranged in the film substrate 100. Here, some of the passive devices may be arranged in the cavities 130 of the base film 110, and the other passive devices may be mounted on the first surface 101 of the base film 110. As a result, the passive device arranging area 115 may be smaller, and thus, the length of routing paths between the passive devices and the first semiconductor chip 200 may be reduced. Therefore, the semiconductor package 1000a and an electronic device including the same may have improved power integrity characteristics.

FIG. 4 is a schematic cross-sectional view of a semiconductor package 1000b according to aspects of the present disclosure.

The semiconductor package 1000b of FIG. 4 is similar to the semiconductor package 1000 of FIGS. 1 and 2 except that it further includes third passive devices 430. In FIG. 4, like reference numerals also appearing in FIGS. 1 and 2 denote like elements as those discussed with reference to FIGS. 1 and 2, and therefore, detailed descriptions thereof will not be repeated below.

Referring to FIG. 4, the semiconductor package 1000b may include the film substrate 100, the first semiconductor chip 200 on the film substrate 100, the first passive devices 400 arranged in the cavities 130 of the base film 110, and the third passive devices 430 arranged on the second surface 103 of the base film 110.

The film substrate 100 may include the base film 110, and the upper wiring layer 120 and a lower wiring layer 122 opposite each other around the base film 110. A conductive via 124, which vertically penetrates through the base film 110 and the insulating layer 140, may be formed in the film substrate 100, and may electrically connect the upper wiring layer 120 with the lower wiring layer 122. Though not shown in FIG. 4, the film substrate 100 may include a protective layer formed on the first and second surfaces 101 and 103 of the base film 110, the protective layer covering at least a part of the upper wiring layer 120 and lower wiring layer 122.

The third passive devices 430 may be arranged in the passive device arranging area 115 (of FIG. 1), and may be electrically connected to the first semiconductor chip 200. The third passive devices 430 may be mounted on the second surface 103 of the base film 110 that is on an opposite side to the first surface 101 of the base film 110, and may be connected to the lower wiring layer 122. In more detail, electrodes of the third passive devices 430 may be electrically connected to the lower wiring layer 122 by a medium such as solder.

As passive devices are separately arranged in the film substrate 100 and on the second surface 103 of the base film 110, the length of routing paths between the passive devices and the first semiconductor chip 200 may be reduced. As a result, the semiconductor package 1000b and an electronic device including the same may have improved power integrity characteristics.

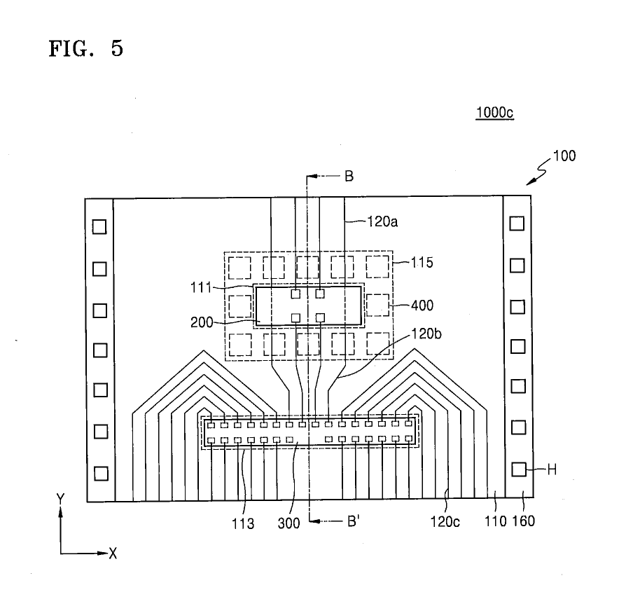

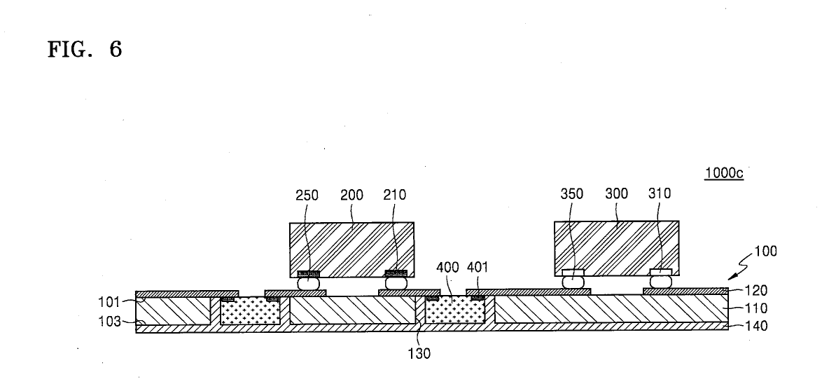

FIG. 5 is a schematic plan view of a semiconductor package 1000c according to aspects of the present disclosure. FIG. 6 is a schematic cross-sectional view illustrating the semiconductor package 1000c taken along a line B-B′ of FIG. 5. In FIGS. 5 and 6, like reference numerals also appearing in FIGS. 1 and 2 denote like elements as those discussed above with reference to FIGS. 1 and 2, and therefore, detailed descriptions thereof will not be repeated below.

Referring to FIGS. 5 and 6, the semiconductor package 1000c may include the film substrate 100, the first semiconductor chip 200 and a second semiconductor chip 300 mounted on the film substrate 100, and the first passive devices 400 disposed in the cavities 130 of the base film 110.

The first and second semiconductor chips 200 and 300 may be mounted on the first surface 101 of the base film 110 by using a flip-chip bonding method. The first and second semiconductor chips 200 and 300 may be mounted on the first mounting area 111 and a second mounting area 113 of the base film 110, respectively. The first and second semiconductor chips 200 and 300 may be disposed spaced apart from each other in a length direction (for example, a second direction Y) of the film substrate 100. The first and second semiconductor chips 200 and 300 may be devices different from each other, and the semiconductor package 1000c may be a system on film (SOF) semiconductor package including various kinds of devices that are mounted on the film substrate 100.

The first semiconductor chip 200 may be a timing controller, and the first passive devices 400 that may be electrically connected to the first semiconductor chip 200 may be disposed around the first semiconductor chip 200. The first passive devices 400 may be arranged

in the cavities 130 of the base film 110. Furthermore, some of the first passive devices 400 may be mounted on the first surface 101 or the second surface 103 of the base film 110, as described above with reference to FIGS. 3 and 4.

Furthermore, the second semiconductor chip 300 may be a display driving chip capable of receiving a signal generated by the first semiconductor chip 200 and capable of generating a signal driving the display panel 3000 (of FIG. 8). Though not shown in FIGS. 5 and 6, passive devices that may be electrically connected to the second semiconductor chip 300 may be disposed in an area adjacent to the second semiconductor chip 300.

The wiring layer 120, which may be formed on the base film 110, may include input wiring patterns 120a, connection wiring patterns 120b, and output wiring patterns 120c.

The input wiring patterns 120a may be paths transmitting a signal voltage received from the source PCB 2000 (of FIG. 8) to the first semiconductor chip 200 and/or the second semiconductor chip 300. In more detail, one of the input wiring patterns 120a connected to the first semiconductor chip 200 may extend toward some of the chip pads 210 of the first semiconductor chip 200 from an upper side of the film substrate 100 contacting the source PCB, and the other one of the input wiring patterns 120a connected to the second semiconductor chip 300 may extend toward some of the chip pads 310 of the second semiconductor chip 300 from the upper side of the film substrate 100 contacting the source PCB. Here, the input wiring patterns 120a connected to the second semiconductor chip 300 may not be electrically connected to the first semiconductor chip 200, and some of the input wiring patterns 120a connected to the second semiconductor chip 300 may pass through the first mounting area 111 on which the first semiconductor chip 200 is mounted.

The connection wiring patterns 120b may be paths transmitting a driving signal generated by the first semiconductor chip 200 to the second semiconductor chip 300. The connection wiring patterns 120b may be extended toward some of the chip pads 310 of the second semiconductor chip 300 from some of the chip pads 210 of the first semiconductor chip 200.

The output wiring patterns 120c may be paths transmitting an image signal generated by the second semiconductor chip 300 to the display panel 3000 (of FIG. 8). The output wiring patterns 120c may be extended to a lower side of the film substrate 100 contacting the display panel 3000 from some of the chip pads 310 of the second semiconductor chip 300 that are disposed in a width direction (for example, a first direction X) of the film substrate 100.

Though not shown in FIGS. 5 and 6, the wiring layer 120 may include bypass wiring patterns not passing through the first and second semiconductor chips 200 and 300. Furthermore, for convenience of understanding, only a part of the input wiring patterns 120a, the connection wiring patterns 120b, and the output wiring patterns 120c are illustrated in FIGS. 5 and 6. However, the number of the input wiring patterns 120a, the connection wiring patterns 120b, and the output wiring patterns 120c may be greater than in FIGS. 5 and 6.

Meanwhile, since the semiconductor package 1000c may have an SOF structure in which the first and second semiconductor chips 200 and 300 are mounted on the film substrate 100 together, devices required for display driving may be disposed further adjacent to a display panel. Therefore, the semiconductor package 1000c and a display device including the same may have improved signal integrity characteristics.

Furthermore, since at least some of the first passive devices 400 are disposed in the film substrate 100 adjacent to the first semiconductor chip 200, the first passive devices 400 may prevent an increase in a length of the film substrate 100 while reducing the length of the routing paths between the first passive devices 400 and the first semiconductor chip 200. Therefore, power integrity characteristics of the semiconductor package 1000c and an electronic device including the same may be improved.

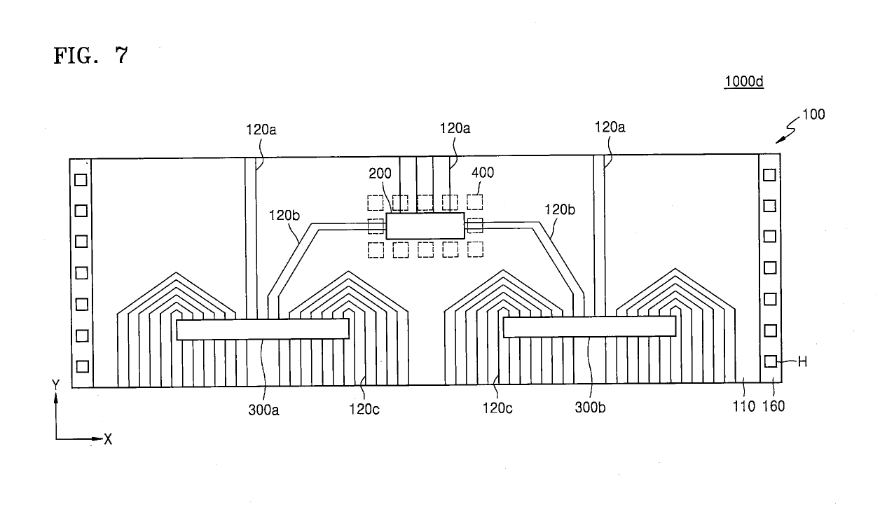

FIG. 7 is a schematic plan view of a semiconductor package 1000d according to aspects of the present disclosure.

The semiconductor package 1000d of FIG. 7 may be similar to the semiconductor package 1000c of FIGS. 5 and 6 except that the semiconductor package 1000d may include second semiconductor chips 300a and 300b. In FIG. 7, like reference numerals also appearing in FIGS. 5 and 6 denote like elements as those discussed above with reference to FIGS. 5 and 6, and therefore, detailed descriptions thereof will not be repeated below.

Referring to FIG. 7, the semiconductor package 1000d may include the film substrate 100, the first semiconductor chip 200 and the second semiconductor chips 300a and 300b mounted on the film substrate 100, and the first passive devices 400 disposed in the film substrate 100. FIG. 7 illustrates that the semiconductor package 1000d may include two of the second semiconductor chips 300a and 300b, but the number of the second semiconductor chips 300a and 300b may be three or more. The first semiconductor chip 200 and the second semiconductor chips 300a and 300b may be devices different from each other. For example, the first semiconductor chip 200 may be a timing controller and the second semiconductor chips 300a and 300b may be display driving chips.

The second semiconductor chips 300a and 300b may be disposed spaced apart from each other in a width direction (for example, a first direction X) of the film substrate 100. Each of the second semiconductor chips 300a and 300b may receive a signal voltage from the source PCB 2000 (described in detail below with reference to FIG. 8) through input wiring patterns 120a. Furthermore, each of the second semiconductor chips 300a and 300b may receive a driving signal from the first semiconductor chip 200 through connection wiring patterns 120b. Here, a part of the connection wiring patterns 120b may connect the second semiconductor chip 300a (illustrated on the left side of FIG. 7) with the first semiconductor chip 200, and the other part of the connection wiring patterns 120b may connect the second semiconductor chip 300b (illustrated on the right side of FIG. 7) with the first semiconductor chip 200.

FIG. 8 is a schematic perspective view of a part of a display device 10000 according to aspects of the present disclosure.

Referring to FIG. 8, the display device 10000 may include at least one semiconductor package 1000, the source PCB 2000, and the display panel 3000.

The source PCB 2000 and the display panel 3000 may be connected to each other by the at least one semiconductor package 1000 disposed therebetween. For example, an anisotropic conductive film may be disposed on a portion where the source PCB 2000 and the at least one semiconductor package 1000 are bonded to each other, and a portion where the display panel 3000 and the at least one semiconductor package 1000 are bonded to each other, the anisotropic conductive film physically and electrically connecting the at least one semiconductor package 1000, the source PCB 2000, and the display panel 3000.

In some embodiments, a single semiconductor package 1000 may be disposed between the source PCB 2000 and the display panel 3000. For example, when the display panel 3000 provides a small display of, for example, a mobile phone, or provides a low-resolution image, the display device 10000 may include a single semiconductor package 1000.

Furthermore, in some embodiments, a plurality of semiconductor packages 1000 may be disposed between the source PCB 2000 and the display panel 3000. For example, when the display panel 3000 provides a larger display of, for example, a television, or provides a high-resolution image, the display device 10000 may include a plurality of semiconductor packages 1000.

The source PCB 2000 may include an interface capable of being connected to an external processor (not shown), and at least one driving component 2100 capable of simultaneously applying power and a signal, such as a driving signal, to at least one semiconductor package 1000.

The display panel 3000 may include a transparent substrate 3100, an image area 3200 formed on the transparent substrate 3100, and a plurality of panel wirings 3300. The transparent substrate 3100 may be, for example, a glass substrate, or a transparent flexible substrate. A plurality of pixels in the image area 3200 may be connected to the plurality of panel wirings 3300. One or more semiconductor packages 1000 may also be connected to the plurality of panel wirings 3300, and thus, the plurality of pixels in the image area 3200 may be operated according to a signal output from the semiconductor package 1000.

The display panel 3000 may be, for example, a liquid crystal display (LCD) panel, a light emitting diode (LED) panel, an organic LED (OLED) panel, and a plasma display panel (PDP).

The at least one semiconductor package 1000 may receive a signal output from the source PCB 2000 and may transmit the signal to the display panel 3000. The at least one semiconductor package 1000 may include the semiconductor package described above with reference to FIGS. 1 through 7. Therefore, the display device 10000 according to aspects of the present disclosure may have improved signal integrity characteristics and power integrity characteristics.

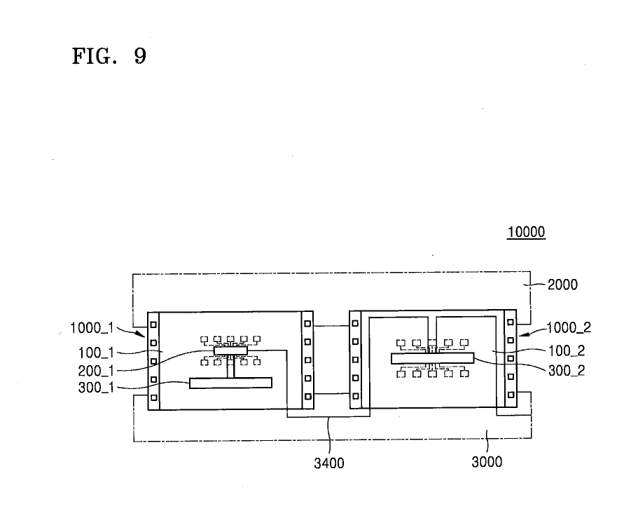

FIG. 9 is a schematic plan view of a part of the display device 10000 according to aspects of the present disclosure.

The display device 10000 may include the source PCB 2000, the display panel 3000, and a first semiconductor package 1000_1 and a second semiconductor package 1000_2 connected to the source PCB 2000 and the display panel 3000.

The first semiconductor package 1000_1 may be an SOF semiconductor package including a timing controller 200_1 and a first display driving chip 300_1, both mounted on a film substrate 100_1. The second semiconductor package 1000_2, unlike the first semiconductor package 1000_1, may include only a second display driving chip 300_2 mounted on a film substrate 100_2.

The display device 10000 may require a plurality of display driving chips and a plurality of timing controllers depending on a size and a required resolution of the display panel 3000. Here, a single timing controller may be formed to apply a driving signal to at least two display driving chips.

For example, the timing controller 200_1 in the first semiconductor package 1000_1 may transmit a driving signal to the first display driving chip 300_1 and the second display driving chip 300_2. The timing controller 200_1 may be connected to the first display driving chip 300_1 through a connection wiring pattern formed on the film substrate 100_1 of the first semiconductor package 1000_1. Furthermore, the timing controller 200_1 may be connected to the second display driving chip 300_2 through a package connection wiring pattern 3400 connecting the first semiconductor package 1000_1 with the second semiconductor package 1000_2. The package connection wiring pattern 3400 may pass through the display panel 3000 or the source PCB 2000.

While the present disclosure has been particularly shown and described with reference to the accompanying drawings, it will be understood that various changes in form and details may be made therein without departing from the scope of the following claims.

What is claimed is:

1. A semiconductor package comprising:
a film substrate comprising a base film including cavities and a wiring layer on the base film;
a first semiconductor chip connected to the wiring layer and mounted on a first surface of the base film; and
a plurality of first passive devices in the cavities of the base film and electrically connected to the first semiconductor chip through the wiring layer.

2. The semiconductor package of claim 1, wherein
the cavities penetrate through the base film,
the wiring layer comprises an upper wiring layer formed on the first surface of the base film, and
the plurality of first passive devices are arranged in the cavities to contact the upper wiring layer in an opposite direction from the first semiconductor chip around the upper wiring layer.

3. The semiconductor package of claim 1, wherein
the film substrate further comprises an insulating layer on at least a portion of a surface of the first passive devices and filling the cavities.

4. The semiconductor package of claim 1, wherein
the base film comprises a first mounting area in which the first semiconductor chip is arranged, and a passive device arranging area in which the first passive devices are arranged, wherein
the first mounting area overlaps the passive device arranging area.

5. The semiconductor package of claim 4, further comprising:
a plurality of second passive devices arranged in the passive device arranging area and electrically connected to the first semiconductor chip through the wiring layer, wherein
the plurality of second passive devices are mounted on the first surface of the base film.

6. The semiconductor package of claim 4, further comprising:
a plurality of second passive devices arranged in the passive device arranging area and electrically connected to the first semiconductor chip through the wiring layer, wherein
the plurality of second passive devices are mounted on a second surface of the base film, the second surface being on an opposite side to the first surface of the base film.

7. The semiconductor package of claim 1, wherein
the first semiconductor chip is a timing controller or a display driving chip.

8. The semiconductor package of claim 1, further comprising:
a second semiconductor chip mounted on the film substrate and electrically connected to the first semiconductor chip by a connection wiring pattern that is a part of the wiring layer, wherein
the second semiconductor chip is different from the first semiconductor chip.

9. The semiconductor package of claim 8, wherein
the second semiconductor chip comprises a plurality of second semiconductor chips, and
the plurality of second semiconductor chips are arranged in a width direction of the film substrate, and respectively connected to the first semiconductor chip by the connection wiring pattern.

10. A display device comprising:
a source printed circuit board (PCB);
a display panel spaced apart from the source PCB and configured to display an image; and
a first semiconductor package between the source PCB and the display panel and electrically connecting the source PCB with the display panel, wherein
the first semiconductor package comprises:
a film substrate comprising a base film and a wiring layer on the base film;
a timing controller on the wiring layer;
a display driving chip on the wiring layer; and
a plurality of passive devices electrically connected to the timing controller, wherein
at least some of the passive devices are buried in the film substrate and contact the wiring layer.

11. The display device of claim 10, wherein
the base film comprises cavities extending through the base film to accommodate the passive devices buried in the film substrate, wherein a number of the cavities corresponds to a number of the passive devices.

12. The display device of claim 11, wherein
the film substrate further comprises an insulating layer filling the cavities, wherein
the insulating layer covers side surfaces and bottom surfaces of the plurality of passive devices.

13. The display device of claim 10, wherein
the base film comprises a first area comprising the timing controller, a second area comprising the display driving chip, and a third area surrounding the first area and comprising the passive devices.

14. The display device of claim 10, wherein
at least one of the plurality of passive devices are on a first surface of the base film, on which the timing controller is mounted, to contact an upper wiring layer on the first surface of the base film, or on a second surface of the base film that is on an opposite side to the first surface of the base film to contact a lower wiring layer on the second surface of the base film.

15. The display device of claim 10, further comprising:
a second semiconductor package between the source PCB and the display panel and connecting the source PCB with the display panel, wherein
the second semiconductor package, which is a chip on film (COF) semiconductor package, comprises a display driving chip, and
the timing controller of the first semiconductor package and the display driving chip of the second semiconductor package are connected to each other through a package connection wiring pattern passing through the source PCB or the display panel.

16. A semiconductor package comprising:
a base film including at least one recess;
a wiring layer on the base film;
a first semiconductor chip connected to the wiring layer and mounted on a first surface of the base film; and
at least one first passive device in the at least one recess of the base film and electrically connected to the first semiconductor chip via the wiring layer.

17. The semiconductor package of claim 16, wherein the wiring layer is on the first surface of the base film and comprises an upper wiring layer, the semiconductor package further comprising a lower wiring layer on a second surface of the base film opposite the first surface.

18. The semiconductor package of claim 17, further comprising at least one second passive device on the lower wiring layer.

19. The semiconductor package of claim 16, wherein the base film further comprises a first mounting area in which the first semiconductor chip is mounted and a passive device arranging area in which the at least one first passive device is located.

20. The semiconductor package of claim 19, wherein the first semiconductor chip comprises a timing controller.
